(19) United States
(12) Patent Application Publication
(10) Pub. No.: US 2023/0420507 A1
(43) Pub. Date: Dec. 28, 2023

(54) GATE ALL AROUND TRANSISTORS ON ALTERNATE SUBSTRATE ORIENTATION

(71) Applicant: Intel Corporation, Santa Clara, CA (US)

(72) Inventors: Ashish Agrawal, Hillsboro, OR (US); Anand Murthy, Portland, OR (US); Jack T. Kavalieros, Portland, OR (US); Rajat K. Paul, Portland, OR (US); Susmita Ghose, Hillsboro, OR (US); Seung Hoon Sung, Portland, OR (US)

(73) Assignee: Intel Corporation, Santa Clara, CA (US)

(21) Appl. No.: 17/847,559

(22) Filed: Jun. 23, 2022

(51) Int. Cl. H01L 29/06; H01L 29/423; H01L 29/66; H01L 29/786

(52) U.S. Cl. CPC H01L 29/0673; H01L 29/42392; H01L 29/66545; H01L 29/66553; H01L 29/78696

(57) ABSTRACT

Semiconductor devices on a substrate with an alternative crystallographic surface orientation. Example devices includes gate-all-around (e.g., nanoribbon and nanosheet) and forksheet transistors. In an example, a substrate having a (110) crystallographic surface orientation forms the basis for the growth of alternating silicon germanium (SiGe) or germanium tin (GeSn) and silicon (Si) semiconductor layers. P-channel transistors may be formed using SiGe or GeSn nanoribbons while n-channel transistors are formed from Si nanoribbons. The crystallographic surface orientation of the SiGe or GeSn nanoribbons will reflect the same crystallographic surface orientation of the substrate, which leads to a higher hole mobility across the SiGe or GeSn nanoribbons and improved device performance.

### FIELD OF THE DISCLOSURE

The present disclosure relates to integrated circuits, and more particularly, to semiconductor devices formed on substrates having different orientations.

### BACKGROUND

As integrated circuits continue to scale downward in size, a number of challenges arise. For instance, reducing the size of memory and logic cells or otherwise increasing transistor density is becoming increasingly more difficult. Different transistor architectures that maximize available semiconductor surfaces to form active channels have been contemplated, including nanowire, nanoribbon or nanosheet (gate-all-around) and forksheet architectures. However, such architectures come with drawbacks with regards to the strain placed on the semiconductor channels. For example, not enough strain can lead to poor hole mobility for p-channel devices, thus degrading device performance. Accordingly, there remain a number of non-trivial challenges with respect to forming certain transistor structures while maintaining a high carrier mobility along the semiconductor channels.

### BRIEF DESCRIPTION OF THE DRAWINGS

FIGS. 1A and 1B are cross-sectional views of semiconductor devices that illustrate n-channel and p-channel devices, in accordance with an embodiment of the present disclosure.

FIGS. 2A-2I are cross-section views that collectively illustrate various stages in an example process for forming semiconductor devices on a substrate having a (110) crystallographic surface orientation, in accordance with some embodiments of the present disclosure.

FIG. 3 illustrates cross-section views of source and drain regions grown over a (100) substrate vs. a (110) substrate, in accordance with some embodiments of the present disclosure.

FIG. 4 illustrates a cross-section view of a chip package containing one or more semiconductor dies, in accordance with some embodiments of the present disclosure.

FIG. 5 is a flowchart of a fabrication process for semiconductor devices formed on a substrate having a (110) crystallographic surface orientation, in accordance with some embodiments of the present disclosure.

FIG. 6 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., tapered sidewalls and rounded corners), and some features may have surface topology or otherwise be non-smooth, given real world limitations of the processing equipment and techniques used.

### DETAILED DESCRIPTION

Semiconductor devices formed on a substrate with an alternative crystallographic surface orientation are herein described. Example devices include gate-all-around (e.g., nanoribbon and nanosheet) and forksheet transistors. According to some embodiments, a substrate having a (110) crystallographic surface orientation forms the basis for the growth of alternating silicon germanium (SiGe) or germanium tin (GeSn) and silicon (Si) semiconductor layers. P-channel transistors may be formed using SiGe or GeSn nanoribbons while n-channel transistors are formed from Si nanoribbons. The crystallographic surface orientation of the SiGe or GeSn nanoribbons will reflect the same crystallographic surface orientation of the substrate, which leads to a higher hole mobility across the SiGe or GeSn nanoribbons and improved performance, with respect to p-channel transistor performance as well as overall hybrid channel performance of a complementary metal oxide semiconductor (CMOS) cell that includes both p-channel and n-channel transistors. Numerous variations and embodiments will be apparent in light of this disclosure.

General Overview

Gate-all-around (GAA) and forksheet device architectures have source, drain and gate structures that are isolated from the sub fin layer to reduce parallel conduction between the source/drain and the substrate and to reduce parasitic capacitance between the gate and the substrate. Usually, such transistors are formed on substrates having a (100) surface orientation. However, nanoribbon channels formed from epitaxially grown semiconductor layers on such substrates can suffer from poor hole mobility due to the crystallographic orientation of the semiconductor layers. Semiconductor materials such as silicon germanium (SiGe) or germanium tin (GeSn) can provide higher hole mobility compared to silicon (Si) for forming p-channel devices, but often require induced strain when formed on a (100) substrate.

Thus, and in accordance with an embodiment of the present disclosure, techniques are provided herein to form semiconductor devices on a substrate having a (110) crystallographic surface orientation to provide better p-channel performance. Although the (110) surface orientation exhibits a lower electron mobility in the n-channel devices (as compared to the (100) surface orientation), a greater increase in hole mobility can be achieved such that the combined effect of using both n-channel and p-channel devices exhibits an overall improved performance. The use of a (110) substrate allows for unstrained SiGe nanoribbons in the p-channel devices, which do not provide sufficient mobility to use effectively on a (100) substrate. Further note that, although nanoribbons may be used in examples herein, the techniques similarly apply to nanosheets and other such relatively thin semiconductor bodies that can be used for transistor channels. To this end, the use of nanosheet (or nanoribbon) is intended to include all such semiconductor bodies. Numerous variations and embodiments will be apparent in light of this disclosure.

According to an embodiment, an integrated circuit includes a substrate having a (110) crystallographic surface orientation, a semiconductor device on the substrate and having one or more semiconductor nanoribbons extending in a first direction between a source region and a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure around the one or more semiconductor nanoribbons and between the first and second spacer structures. Each of the one or more semiconductor nanoribbons include silicon and germanium.

According to another embodiment, an integrated circuit includes a semiconductor device having one or more semiconductor nanoribbons extending in a first direction between a source region and a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure around the one or more semiconductor nanoribbons and between the first and second spacer structures. Each of the one or more semiconductor nanoribbons includes silicon and germanium, and the one or more semiconductor nanoribbons have a (110) crystallographic surface orientation along surfaces that are parallel with a plane extending in the first direction and the second direction.

According to another embodiment, a method of forming an integrated circuit includes providing a substrate having a (110) crystallographic surface orientation; epitaxially growing first material layers alternating with second material layers on the substrate, the second material layers comprising silicon and germanium; forming a multilayer fin from the first material layers and the second material layers; forming sidewall spacer structures around exposed ends of the second material layers; removing the first material layers to form suspended second material layers; forming source and drain regions coupled to the exposed ends of the second material layers; and forming a gate structure around the suspended second material layers and between the sidewall spacer structures.

According to another embodiment, an integrated circuit includes a substrate having a (110) crystallographic surface orientation, a semiconductor device on the substrate and having one or more semiconductor nanoribbons extending in a first direction between a source region and a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure around the one or more semiconductor nanoribbons and between the first and second spacer structures. Each of the one or more semiconductor nanoribbons include germanium and tin.

The techniques can be used with any type of non-planar transistors but are especially useful for nanowire and nanoribbon transistors (sometimes called GAA transistors or forksheet transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED or NanoED), and reflection electron microscopy (REM); composition mapping; x-ray crystallography or diffraction (XRD); Raman spectroscopy; energy-dispersive x-ray spectroscopy (EDX); electron energy loss spectroscopy (EELS); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the use of SiGe or GeSn nanoribbons for some devices (e.g., p-channel devices) and Si nanoribbons having little to no Ge (or Sn) for other devices (e.g., n-channel devices). For example, TEM and/or SEM cross-sections, EDX, and EELS can be used to reveal SiGe or GeSn nanoribbons having a substantially constant Ge or Sn concentration along the entire length of the nanoribbons between the source and drain regions. In some embodiments, the SiGe or GeSn nanoribbons may lie on different horizontal planes compares to Si nanoribbons of other devices (e.g., the SiGe or GeSn nanoribbons are different heights off of the substrate surface compared to the Si nanoribbons). In some embodiments, TEM and/or SEM cross-sections taken across the source or drain regions along the same direction as the length of the nanoribbons will not have visible crystal facets owing to the growth profile of the source and drain regions on the (110) substrate. Note that nanoribbons are used in these examples, but the present description equally applies to nanosheet and forksheet configurations.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

Architecture

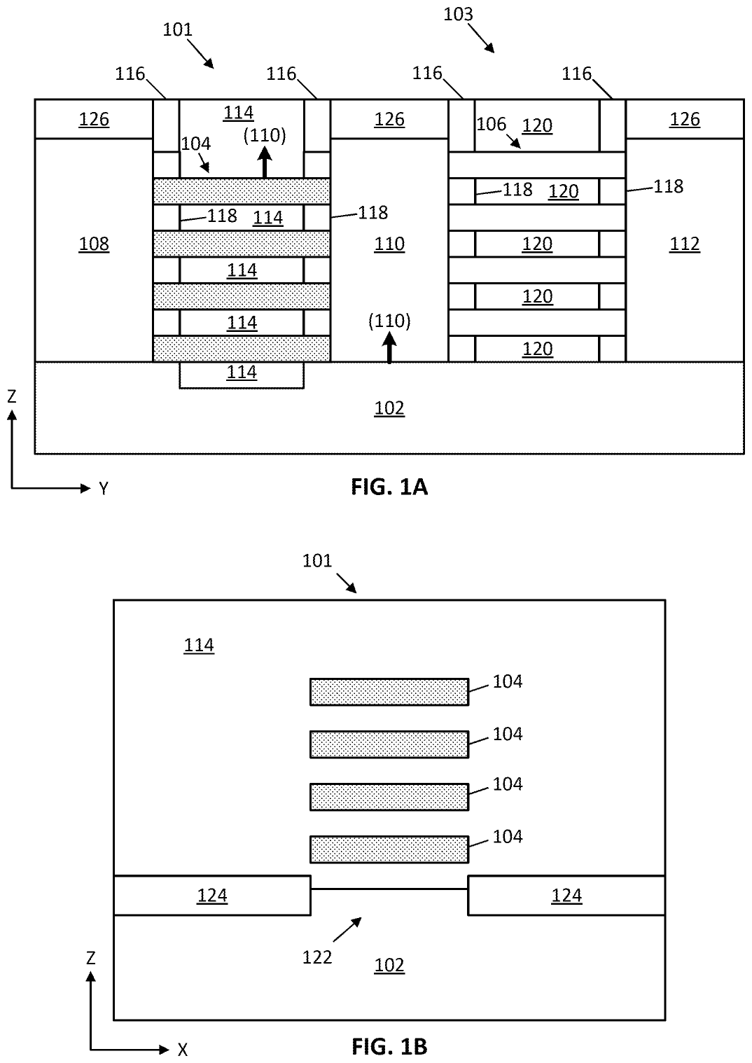

FIG. 1A is a cross-sectional view taken across a first semiconductor device 101 and a second semiconductor device 103, according to an embodiment of the present disclosure. FIG. 1B is a cross-sectional view taken in an orthogonal direction across first semiconductor device 101. Each of first and second semiconductor devices 101 and 103 may be any type of non-planar metal oxide semiconductor (MOS) transistor, such as a tri-gate, gate-all-around (GAA), or forksheet transistor, although other transistor topologies and types could also benefit from the techniques provided herein. The illustrated embodiments herein use the GAA structure. FIG. 1A provides a cross-section view taken across first semiconductor device 101 and second semiconductor device 103 in a first direction (e.g., Y-direction). FIG. 1B is taken across first semiconductor device 101 in a second direction (e.g., X-direction) while orthogonal to the first direction. Both cross-sections also extend in a third direction (e.g., Z-direction) that is orthogonal to both the first direction and the second direction.

First and second semiconductor devices 101 and 103 together represent a portion of an integrated circuit that may contain any number of similar and/or other semiconductor devices. Additionally, first and second semiconductor devices 101 and 103 are provided side-by-side for clarity and for ease of discussion when comparing and contrasting the devices. However, second semiconductor device 103 could exist anywhere else within the integrated circuit and is not required to be linked with first semiconductor device 101 via a shared source or drain region. The arrangement of first semiconductor device 101 sharing a source or drain region with second semiconductor device 103 may be used in various circuit or cell structures, such as an inverter, logic cell, memory cell, or complementary metal oxide semiconductor (CMOS) cell.

As can be seen, semiconductor devices 101 and 103 are formed on a substrate 102, in this example case. Any number of other semiconductor devices can be formed on substrate 102, but two are illustrated here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used.

First semiconductor device 101 may include any number of semiconductor nanoribbons 104 while second semiconductor device 103 similarly may include any number of semiconductor nanoribbons 106. Nanoribbons 104 may extend between a source region 108 and a drain region 110. Likewise, nanoribbons 106 may extend between a source region 112 and drain region 110. Any source region may also act as a drain region and vice versa, depending on the application. Furthermore, as noted above, nanoribbons 106 of second semiconductor device 103 may extend between source region 112 and a drain region that is different from drain region 110, according to other example embodiments. In some embodiments, any of nanoribbons 104 or nanoribbons 106 are shaped like nanowires having a substantially circular cross-section.

According to some embodiments, nanoribbons 104 of first semiconductor device 101 are not co-planar with nanoribbons 106 of second semiconductor device 103. For example, nanoribbons 104 may exhibit a staggered relationship with nanoribbons 106, such that nanoribbons 104 are co-planar with the spaces between nanoribbons 106. The difference in heights between nanoribbons 104 and nanoribbons 106 is created due to which layers are removed during the fabrication of the suspended nanoribbons, as discussed in more detail herein.

In some embodiments, semiconductor devices 101 and 103 have an equal number of nanoribbons, while in other embodiments they have an unequal number of nanoribbons. In some embodiments, each of nanoribbons 104 and nanoribbons 106 are formed from a fin of alternating material layers (e.g., alternating layers of silicon and silicon germanium) where sacrificial material layers are removed between nanoribbons 104 and nanoribbons 106. In some embodiments, the sacrificial layers removed from the fin of first semiconductor device 101 are different from those removed from the fin of second semiconductor device 103, yielding nanoribbons at different heights between the two semiconductor devices. Each of nanoribbons 104 and nanoribbons 106 may include the same semiconductor material as substrate 102, or not. In still other cases, substrate 102 is removed. In some such cases, there may be, for example one or more backside interconnect and/or contact layers. According to some embodiments, semiconductor device 101 is a p-channel device having semiconductor nanoribbons 104 that include both silicon and germanium and semiconductor device 103 is an n-channel device having semiconductor nanoribbons 106 that include silicon and little to no germanium (e.g., less than 1% Ge). According to some embodiments, semiconductor device 101 is a p-channel device having semiconductor nanoribbons 104 that include both germanium and tin.

According to some embodiments, source and drain regions 108/110/112 are epitaxial regions that are provided using an etch-and-replace process. In other embodiments any of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance and/or induce strain. In any such cases, the composition and doping of the source and drain regions may be the same or different, depending on the polarity of the transistors. Any number of source and drain configurations and materials can be used.

According to some embodiments, the fins or semiconductor material can be formed of material deposited over the underlying substrate 102. In one such example case, the fins include alternating layers of material (e.g., alternating layers of Si and SiGe) that facilitates forming of nanowires and nanoribbons during a gate forming process where one type of the alternating layers are selectively etched away so as to release the other type of alternating layers within the channel region, so that a gate-all-around (GAA) process can then be carried out. The alternating layers can be blanket deposited and then etched into fins, or deposited into fin-shaped trenches.

According to some embodiments, a first gate structure 114 is provided over each of nanoribbons 104 between spacer structures 116 and internal spacers 118. Similarly, a second gate structure 120 is provided over each of nanoribbons 106 between spacer structures 116 and internal spacers 118. Each of first and second gate structures 114 and 120 include both a gate dielectric around the corresponding nanoribbons and a gate electrode over the gate dielectric. The gate dielectric may also be deposited along sidewalls and the bottom of the trench between spacer structures 116 and internal spacers 118. The gate dielectric may include a single material layer or multiple stacked material layers. In some embodiments, the gate dielectric includes a first dielectric layer such as silicon oxide and a second dielectric layer that includes a high-k material such as hafnium oxide. The hafnium oxide may be doped with an element to affect the threshold voltage of the given semiconductor device. According to some embodiments, the doping element used in the gate dielectric is lanthanum.

According to some embodiments, first and second gate structures 114 and 120 include a gate electrode that extends over the gate dielectric around each of nanoribbons 104 and 106, respectively. The gate electrode may include any sufficiently conductive material such as a metal (e.g., tungsten, cobalt, titanium, ruthenium, aluminum, molybdenum), metal alloy, or doped polysilicon. According to some embodiments, the gate electrode may be interrupted between any other semiconductor devices by a gate cut structure. In some embodiments, the gate electrode includes one or more work-function metals around the corresponding nanoribbons. For example, first semiconductor device 101 may be a p-channel device that includes SiGe or GeSn nanoribbons 104 and includes a work-function metal having titanium around nanoribbons 104. In another example, second semiconductor device 103 is an n-channel device that includes Si nanoribbons 106 and includes a work-function metal having tungsten around nanoribbons 106. In some embodiments, first and second gate electrodes 114 and 120 each includes a fill metal or other conductive material around the work-function metal(s) to provide the whole gate electrode structure.

According to some embodiments, first gate structure 114 extends below the bottom nanoribbon 104 of first semiconductor device 101 and beneath a top surface of substrate 102. As shown more clearly in FIG. 1B, a sub fin 122 beneath nanoribbons 104 is recessed beneath a top surface of a dielectric fill 124 on either side of first semiconductor device 101. The recessing of sub fin 122 may be performed to release the bottom nanoribbon 104, as will be discussed in more detail herein. Dielectric fill 124 may act as shallow trench isolation (STI) structures between first semiconductor device 101 and any neighboring semiconductor devices. Dielectric fill 124 may be any suitable dielectric material, such as, for example, silicon dioxide, aluminum oxide, or silicon oxycarbonitride.

According to some embodiments, substrate 102 has a (110) crystallographic surface orientation as identified by the bold arrow normal to the surface of substrate 102. The surface orientation of the silicon lattice affects the growth profile of the semiconductor layers that are used to form each of nanoribbons 104 and 106. Thus, according to some embodiments, nanoribbons 104 and 106 similarly have a (110) crystallographic surface orientation along all surfaces that are parallel with the top surface of substrate 102. Put another way, nanoribbons 104 and 106 have a (110) crystallographic surface orientation along all surfaces that are parallel with a plane that extends along a length vector of nanoribbons 104 and 106 and along a vector that extends into and out of the page. The (110) surface orientation of nanoribbons 104 provides a greater hole mobility along those surfaces that extend between source region 108 and drain region 110, according to some embodiments.

According to some embodiments, nanoribbons 104 include both Si and Ge with a Ge concentration greater than 20%, greater than 30%, greater than 40%, greater than 50%, greater than 60%, greater than 70%, greater than 80%, or greater than 90%, with Si making up the majority of the remaining concentration. According to some embodiments, nanoribbons 104 include both Ge and Sn with a Sn concentration greater than 20%, greater than 30%, greater than 40%, greater than 50%, greater than 60%, greater than 70%, greater than 80%, or greater than 90%, with Ge making up the majority of the remaining concentration. Nanoribbons 106 include Si and substantially no Ge or Sn, such as less than 1% Ge and less than 1% Sn. It should be understood that having less than 1% includes the possibility of having none at all.

In the case of SiGe nanoribbons, the concentration of Ge may remain substantially consistent (e.g., within 5%) along the entire length of nanoribbons 104 extending between source region 108 and drain region 110. In some embodiments, the concentration of Ge along the length of nanoribbons 104 between spacer structures 116 is substantially the same as the concentration of Ge at each of the opposite ends of nanoribbons 104 respectively abutting source region 108 and drain region 110.

In the case of GeSn nanoribbons, the concentration of Sn may remain substantially consistent (e.g., within 5%) along the entire length of nanoribbons 104 extending between source region 108 and drain region 110. In some embodiments, the concentration of Sn along the length of nanoribbons 104 between spacer structures 116 is substantially the same as the concentration of Sn at each of the opposite ends of nanoribbons 104 respectively abutting source region 108 and drain region 110.

A conductive contact 126 may be formed over each of source and drain regions 108/110/112 to provide electrical connections to each of source and drain regions 108/110/112. Conductive contact 126 can include any suitable conductive material, such as tungsten, copper, cobalt, titanium, ruthenium, or tantalum. Frontside and backside interconnect structures may also be formed, as will be appreciated.

Fabrication Methodology

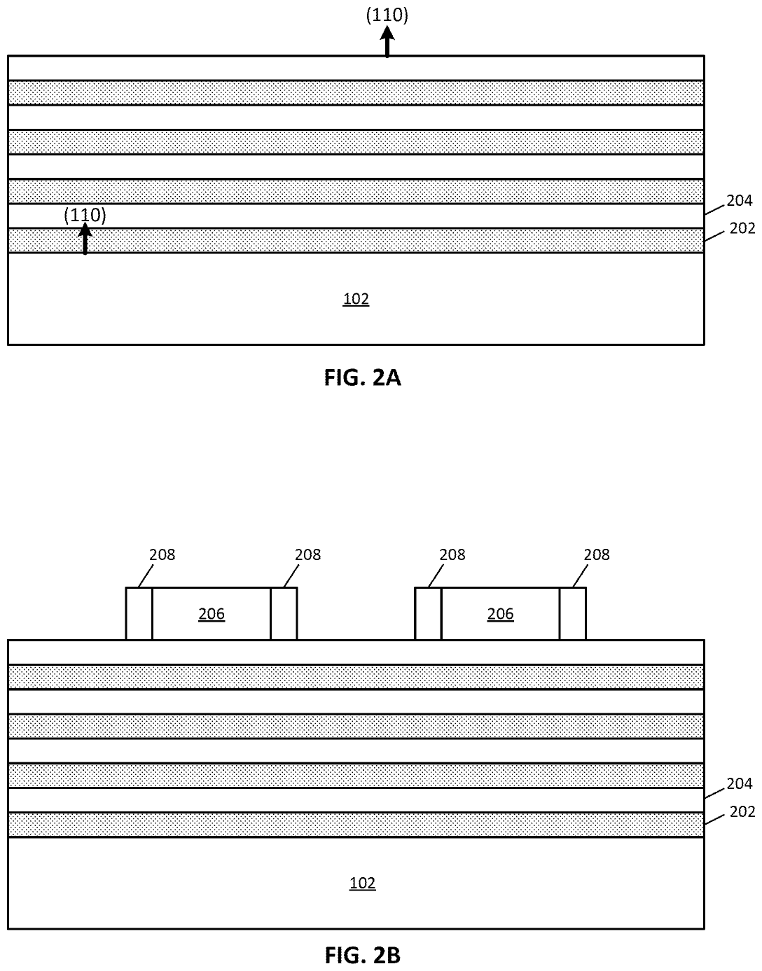

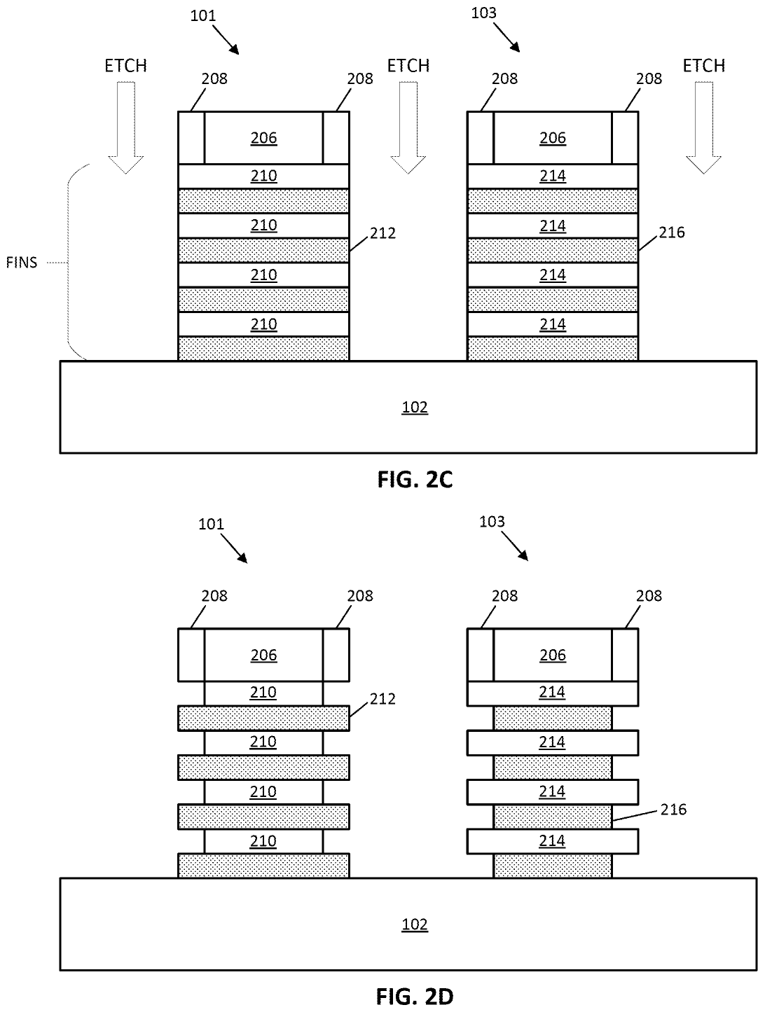

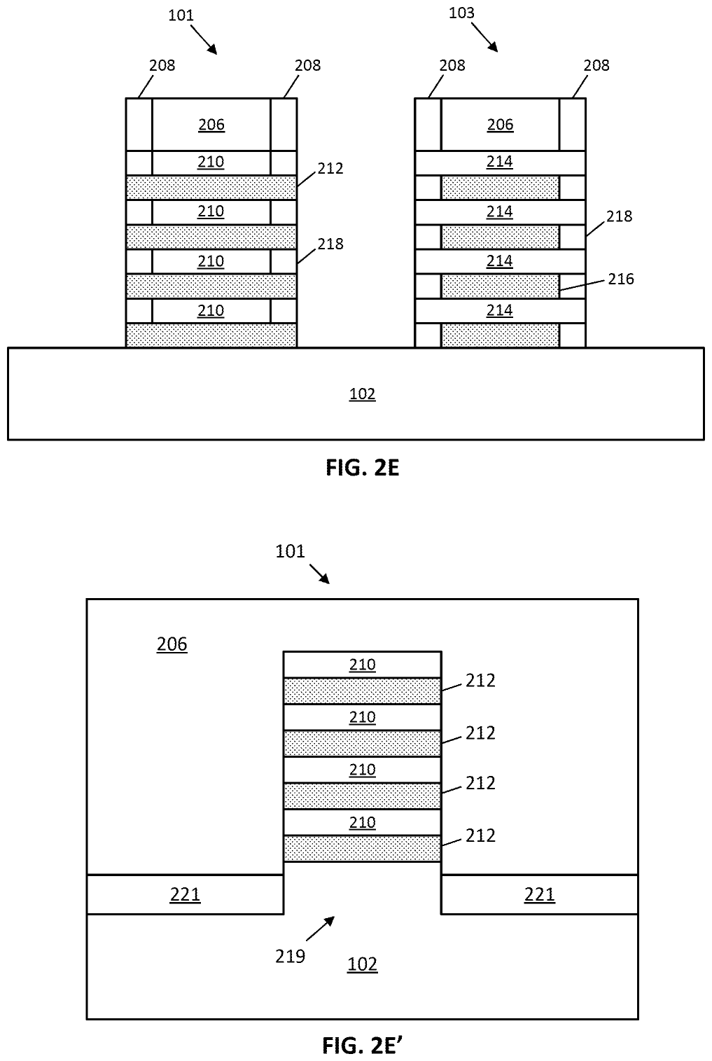

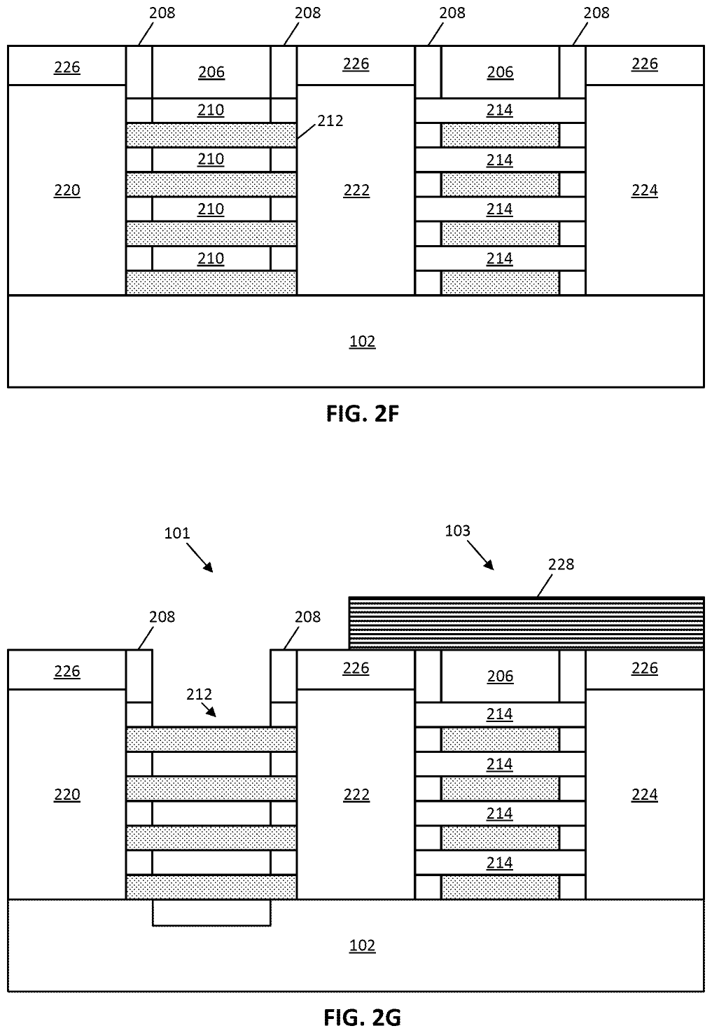

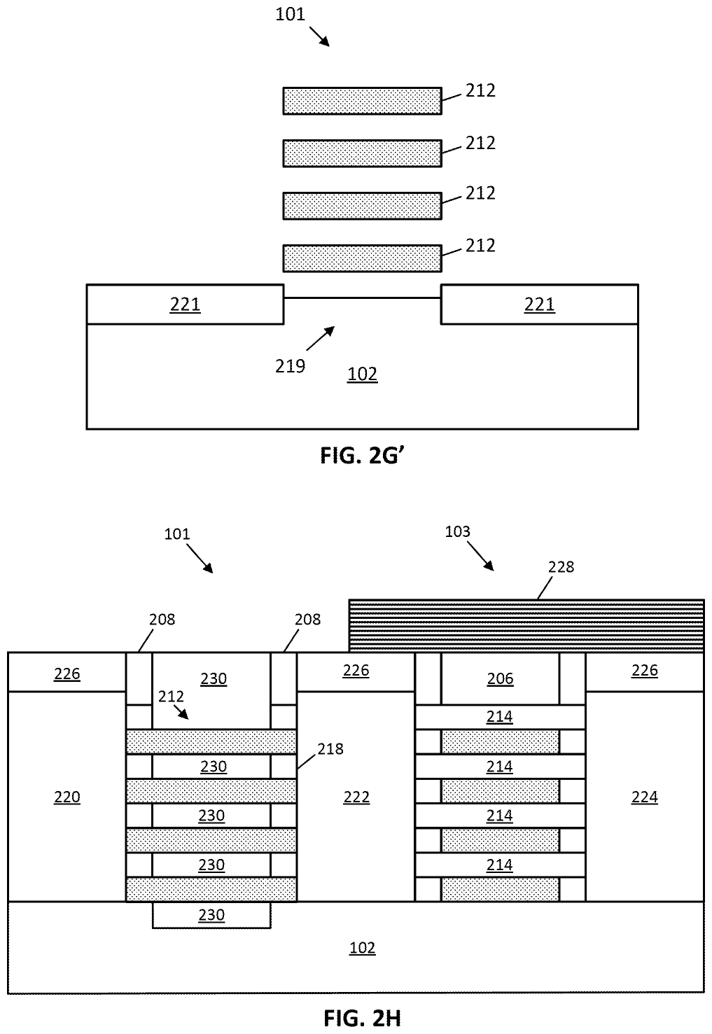

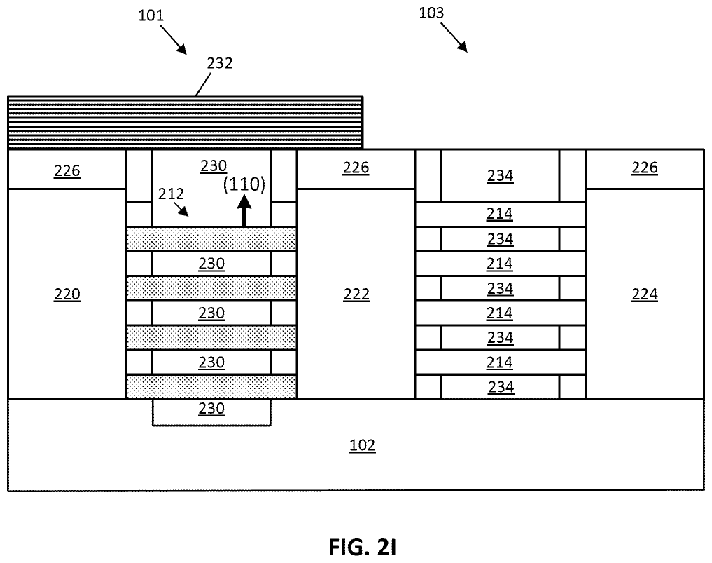

FIGS. 2A-2I include cross-sectional views that collectively illustrate an example process for forming an integrated circuit configured with semiconductor devices formed on a (110) substrate, according to some embodiments. Each figure shows an example structure that results from the process flow up to that point in time, so the depicted structure evolves as the process flow continues, culminating in the structure shown in FIG. 2I, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates substrate 102 having a series of material layers formed over the substrate, according to an embodiment of the present disclosure. Alternating material layers may be deposited over substrate 102 including first layers 202 alternating with second layers 204. Any number of alternating first layers 202 and second layers 204 may be deposited over substrate 102. It should be noted that the cross section illustrated in FIG. 2A is taken along the length of a fin extending in a first direction and formed from the multiple material layers.

According to some embodiments, first layers 202 have a different material composition than second layers 204. In some embodiments, first layers 202 are silicon germanium (SiGe) or germanium tin (GeSn) while second layers 204 include a different semiconductor material such as silicon (Si), SiGe, germanium, or III-V materials like indium phosphide (InP) or gallium arsenide (GaAs). In examples where SiGe is used in each of first layers 202 and in second layers 204, the germanium concentration is different between first layers 202 and second layers 204. For example, first layers 202 may include a higher germanium content compared to second layers 204. Either of both of first layers 202 and second layers 204 may be doped with either n-type dopants (to produce a p-channel transistor) or p-type dopants (to produce an n-channel transistor).

While dimensions can vary from one example embodiment to the next, the thickness of each first layer 202 may be between about 5 nm and about 20 nm. In some embodiments, the thickness of each first layer 202 is substantially the same (e.g., within 1-2 nm). The thickness of each of second layers 204 may be about the same as the thickness of each first layer 202 (e.g., about 5-20 nm). Each of first layers 202 and second layers 204 may be deposited using any known material deposition technique to epitaxially form the various layers, such as chemical vapor deposition (CVD), plasma-enhanced chemical vapor deposition (PECVD), or atomic layer deposition (ALD).

As discussed above, substrate 102 has a (110) crystallographic surface orientation as identified by the bold arrow normal to the surface of substrate 102. The surface orientation of the silicon lattice affects the growth profile of each of the semiconductor layers 202/204 formed on it. Thus, according to some embodiments, each of first layers 202 and second layers 204 similarly have a (110) crystallographic surface orientation along all surfaces that are parallel with the top surface of substrate 102.

FIG. 2B illustrates a cross-sectional view of the structure shown in FIG. 2A following the formation of sacrificial gate structures 206 and sidewall spacers 208 over the alternating layer structure of the fin, according to an embodiment. Sacrificial gate structures 206 may run in an orthogonal direction (e.g., a second direction) to the length of the fin (e.g., the first direction) and may include any material that can be safely removed later in the process without etching or otherwise damaging any portions of the fin or of spacer structures 208. In some embodiments, sacrificial gate structures 206 include polysilicon. Spacer structures 208 may be formed using an etch-back process where spacer material is deposited everywhere and then anisotropically etched to leave the material only on sidewalls of structures including sacrificial gate structures 206. Spacer structures 208 may include a dielectric material, such as silicon nitride, silicon oxy-nitride, or any formulation of those layers incorporating carbon or boron dopants. Sacrificial gate structures 206 together with spacer structures 208 define portions of the fin that will be used to form first and second semiconductor devices, as discussed further herein.

FIG. 2C illustrates a cross-sectional view of the structure shown in FIG. 2B following the removal of the exposed fin not under sacrificial gate structures 206 and sidewall spacers 208, according to an embodiment of the present disclosure. According to some embodiments, the various alternating material layers are etched at substantially the same rate using an anisotropic RIE process. In some embodiments, some undercutting occurs along the edges of the resulting fins beneath spacer structures 208 such that the length of a given fin is not exactly the same as a sum of the widths of spacer structures 208 and a width of sacrificial gate structure 206. The RIE process may also etch into substrate 102 thus recessing portions of substrate 102 on either side of any of the fins. According to some embodiments, a first fin of first semiconductor device 101 includes first layers 210 alternating with second layers 212, while a second fin of second semiconductor device 103 includes third semiconductor layers 214 alternating with fourth semiconductor layers 216. According to some embodiments, first and third layers 210 and 214 have the same material composition and second and fourth layers 212 and 216 have the same material composition.

FIG. 2D illustrates a cross-sectional view of the structure shown in FIG. 2C following the removal of portions of first layers 210 from first semiconductor device 101 and portions of fourth layers 216 from second semiconductor device 103, according to an embodiment of the present disclosure. Different isotropic etching processes may be used to remove the layers from the different semiconductor devices. In an example, first layers 210 and third layers 214 are silicon layers, while second layers 212 and fourth layers 216 are SiGe or GeSn layers. Accordingly, a first isotropic etch may be performed to laterally recess the ends of first layers 210, while etching comparatively little of second layers 212 in first semiconductor device 101. A second isotropic etch may be performed to laterally recess the ends of fourth layers 216, while etching comparatively little of third layers 214 in second semiconductor device 103. Second semiconductor device 103 may be protected during the etching of first layers 210 of first semiconductor device 101, and first semiconductor device 101 may be protected during the etching of fourth layers 216 of second semiconductor device 103.

FIG. 2E illustrates a cross-sectional view of the structure shown in FIG. 2D following the formation of internal spacers 218, according to an embodiment of the present disclosure. Internal spacers 218 may have a material composition that is similar to or the exact same as spacer structures 208. Accordingly, internal spacers 218 may be any suitable dielectric material that exhibits high etch selectively to semiconductor materials such as silicon and/or silicon germanium. Internal spacers 218 may be conformally deposited over the sides of the fin structures using a CVD process like ALD and then etched back using an isotropic etching process to expose the ends of second layers 212 of first semiconductor device 101 and the ends of third layers 214 of second semiconductor device 103.

FIG. 2E′ illustrates an orthogonal cross-sectional view taken across first semiconductor device 101 during the same fabrication stage as illustrated in FIG. 2E. Sacrificial gate structure 206 surrounds the fin of alternating first layers 210 and second layers 212. The fin also includes a sub fin 219 that may be an integral part of substrate 102 (e.g., formed from substrate 102). A dielectric fill 221 is present on either side of sub fin 219. Dielectric fill 221 may act as shallow trench isolation (STI) structures between first semiconductor device 101 and any neighboring semiconductor devices. Dielectric fill 221 may be any suitable dielectric material, such as, for example, silicon dioxide, aluminum oxide, or silicon oxycarbonitride.

According to some embodiments, a top surface of sub fin 219 is above a top surface of dielectric fill 221. In other words, dielectric fill 221 is recessed below a top surface of sub fin 219 when it is being formed, thus exposing at least a portion of sub fin 219 above dielectric fill 221. A portion of sub fin 219 is exposed to allow for the bottom second layer 212 to be released into a nanoribbon, as discussed in more detail herein.

FIG. 2F illustrates a cross-sectional view of the structure shown in FIG. 2E following the formation of source and drain regions, according to an embodiment of the present disclosure. According to an embodiment, a source region 220 is formed at first ends of second layers 212 and a drain region 222 is formed between second ends of second layers 212 and first ends of third layers 214. Another source region 224 may be formed at second ends of third layers 214. As noted above, any of source and drain regions 220/222/224 can act as either a source or drain depending on the application. In some examples, source and drain regions 220/222/224 are epitaxially grown from the ends of second layers 212 and third layers 214. Any semiconductor materials suitable for source and drain regions 220/222/224 can be used (e.g., group IV and group III-V semiconductor materials). Source and drain regions 220/222/224 may include multiple layers such as liners and capping layers to improve contact resistance. In any such cases, the composition and doping of source and drain regions 220/222/224 may be the same or different, depending on the polarity of the transistors. Any number of source and drain configurations and materials can be used.

A dielectric cap layer 226 may be formed over each of source and drain regions 220/222/224, according to some embodiments. Dielectric cap layer 226 allows for a planarized structure, such that the top surface of sacrificial gate structure 206 is co-planar with the top surface of dielectric cap layer 226. Dielectric cap layer 226 may be any suitable dielectric material, such as silicon oxide, aluminum oxide, silicon nitride, or silicon oxycarbonitride.

FIG. 2G illustrates a cross-sectional view of the structure shown in FIG. 2F following the removal of the sacrificial gate structure 206 and first layers 210 of first semiconductor device 101, according to an embodiment of the present disclosure. A masking layer 228 may first be patterned over second semiconductor device 103 to protect it from the etching process that removes sacrificial gate structure 206 and first layers 210 from first semiconductor device 101. Masking layer 228 may be a carbon hard mask (CHM) or any other type of photoresist. It should be understood that masking layer 228 may be patterned to protect any number of semiconductor devices while leaving any number of other semiconductor devices exposed. In some embodiments, masking layer 228 is patterned to protect one or more n-channel devices while leaving one or more other p-channel devices exposed.

The exposed sacrificial gate structure 206 may be removed using any wet or dry isotropic process thus exposing the alternating layer stack of the fin within the trench left behind after the removal of sacrificial gate structure 206. Once sacrificial gate structure 206 has been removed, the exposed first layers 210 may also be removed using a selective isotropic etching process that removes the material of first layers 210 but does not remove (or removes very little of) second layers 212. In one example, first layers 210 are silicon layers that are removed using an isotropic silicon etchant gas while second layers 212 are silicon germanium (SiGe) or germanium tin (GeSn). At this point, the suspended second layers 212 form nanoribbons or nanowires that extend between source and drain regions 220/222. According to some embodiments, releasing second layers 212 includes releasing the bottom-most second layer 212, which involves removing a portion of the sub fin beneath the alternating layer stack. FIG. 2G′ illustrates an orthogonal cross-sectional view taken across first semiconductor device 101 during the same fabrication stage as illustrated in FIG. 2G. Since at least a portion of sub fin 219 was exposed above the top surface of dielectric fill 221, an isotropic etching process can be used to remove a top portion of sub fin 219, thus releasing the bottom second layer 212. In some embodiments, the same isotropic etching process used to remove first layers 210 is also used to remove the top portion of sub fin 219 (e.g., first layers 210 and sub fin 219 comprise substantially the same material).

FIG. 2H illustrates a cross-sectional view of the structure shown in FIG. 2G following the formation of a first gate structure 230 around the suspended second layers 212, according to an embodiment of the present disclosure. As noted above, first gate structure 230 includes a gate dielectric and a gate electrode. Note that first gate structure 230 can wrap around second layers 212 in some configurations (e.g., nanoribbons) or can be on multiple sides of second layers 212 in other configurations (e.g., forksheet).

The gate dielectric may be conformally deposited around second layers 212 using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on second layers 212, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-K material can be nitridized to improve its aging resistance.

The gate electrode may be deposited over the gate dielectric and can be any standard or proprietary gate structure that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more work-function layers, resistance-reducing layers, and/or barrier layers. In one example, first semiconductor device 101 is a PMOS device and the work-function layers include, for example, p-type work-function materials (e.g., titanium nitride). In the case of an NMOS device, n-type work-function materials can include titanium aluminum carbide.

FIG. 2I depicts the cross-section view of the structure shown in FIG. 2H following the completion of the second semiconductor device 103, according to an embodiment of the present disclosure. Another masking layer 232 is formed to protect first semiconductor device 101 while exposing second semiconductor device 103. According to some embodiments, masking layer 232 may be used to protect any number of semiconductor devices that have already had their gate structures formed. Furthermore, any number of semiconductor devices may be exposed, such as second semiconductor device 103. A similar process to that described above for first semiconductor device 101 is then performed to remove sacrificial gate structure 206 and fourth layers 216 to yield suspended third layers 214 that act as nanoribbons extending between drain region 222 and source region 224. As noted above, since the removed first layers 210 from first semiconductor device 101 where different material layers at different heights than the removed fourth layers 216 from second semiconductor device 103, the nanoribbons (e.g., second layers 212) of first semiconductor device 101 are at different staggered heights than the nanoribbons (e.g., third layers 214) of second semiconductor device 103.

A second gate structure 234 is formed around the suspended third layers 214, according to an embodiment of the present disclosure. Like first gate structure 230, second gate structure 234 includes a gate dielectric and a gate electrode. According to some embodiments, second semiconductor device 103 is an n-channel device and thus second gate structure 234 includes one or more n-type work-function layers.

According to some embodiments, first semiconductor device 101 is representative of one or more p-channel devices in the integrated circuit and second semiconductor device 103 is representative of one or more n-channel devices in the integrated circuit. The material composition of second layers 212 is different from third layers 214 owing to the removal of different material layers from each of the fins. For example, second layers 212 include silicon and germanium (e.g., at least 20% Ge) or include both germanium and tin (e.g., at least 20% Sn), while third layers 214 include silicon and substantially no germanium and no tin (e.g., less than 1% germanium and tin).

As discussed above, having second layers 212 with a (110) crystallographic surface orientation allows for second layers 212 to be unstrained SiGe or GeSn. However, it should be noted that further inducing strain upon second layers 212 can provide an additional increase to the hole mobility and enhance the device performance. In some embodiments, compressive strain can be induced by annealing second layers 212 to drive the Ge or Sn inwards and provide a Ge or Sn concentration gradient along the entire length of second layers 212. Further details regarding this process can be found in co-owned U.S. application Ser. No. 17/523,710, filed Nov. 10, 2021, the disclosure of which is incorporated by reference herein in its entirety. In some embodiments, compressive strain can be induced upon Si nanoribbons used in a p-channel device by depositing a SiGe or GeSn cladding around the Si nanoribbons and annealing to drive the Ge or Sn inwards. This creates nanoribbons having a middle portion with SiGe or GeSn and end portions having Si, thus creating a compressive stress along the nanoribbons. Further details regarding this process can be found in co-owned U.S. application Ser. No. 17/523,711, filed Nov. 10, 2021, the disclosure of which is incorporated by reference herein in its entirety.

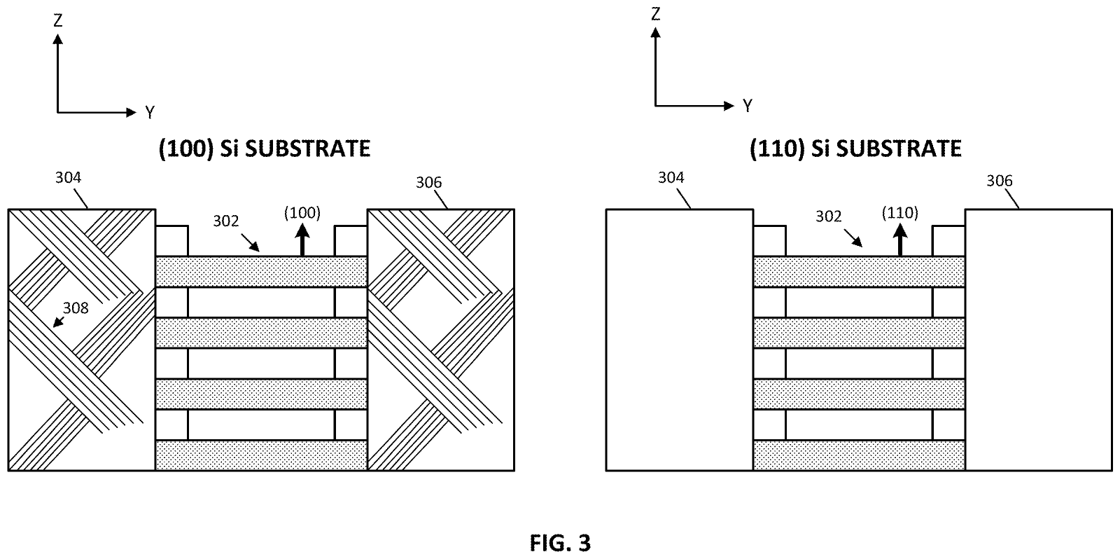

FIG. 3 illustrates example cross-sections taken along the length of nanoribbons 302 extending between a source region 304 and a drain region 306 for different substrate crystallographic surface orientations. The cross-sections are taken along the first direction (e.g., Y-direction) and along the third direction (e.g., Z-direction). In the example of a (100) substrate, nanoribbons 302 exhibit a similar (100) surface orientation. The epitaxial growth of source region 304 and drain region 306 from the ends of nanoribbons 302 having the (100) orientation exhibit a crystalline growth profile showing facets 308 along the illustrated cross-section. Any number of facets 308 may be visible. In contrast, source region 304 and drain region 306 exhibit no visible facets along the same cross-section when grown from the ends of nanoribbons 302 having a (110) surface orientation. The facets may be visible along other planes since the crystalline growth of the source region 304 and drain region 306 is along a different direction due to the difference in the crystallographic surface orientation of nanoribbons 302. So, for example, the source region 304 and the drain region 306 nucleated from nanoribbons or nanosheets 302 having a (100) surface orientation have visible crystal facets along a cross-section that extends along the Y-direction and the Z-direction, and the source region 304 and the drain region 306 nucleated from nanoribbons or nanosheets 302 having a (110) surface orientation have no visible crystal facets along that same cross-section which extends along the Y-direction and the Z-direction (Y being orthogonal to Z).

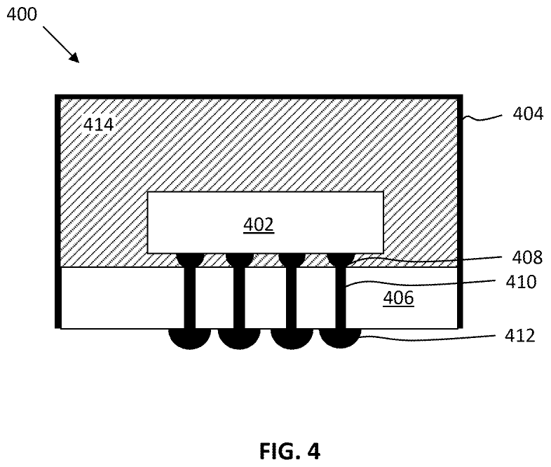

FIG. 4 illustrates an example embodiment of a chip package 400, in accordance with an embodiment of the present disclosure. As can be seen, chip package 400 includes one or more dies 402. One or more dies 402 may include at least one integrated circuit having semiconductor devices, such as any of the semiconductor devices disclosed herein. One or more dies 402 may include any other circuitry used to interface with other devices formed on the dies, or other devices connected to chip package 400, in some example configurations.

As can be further seen, chip package 400 includes a housing 404 that is bonded to a package substrate 406. The housing 404 may be any standard or proprietary housing, and may provide, for example, electromagnetic shielding and environmental protection for the components of chip package 400. The one or more dies 402 may be conductively coupled to a package substrate 406 using connections 408, which may be implemented with any number of standard or proprietary connection mechanisms, such as solder bumps, ball grid array (BGA), pins, or wire bonds, to name a few examples. Package substrate 406 may be any standard or proprietary package substrate, but in some cases includes a dielectric material having conductive pathways (e.g., including conductive vias and lines) extending through the dielectric material between the faces of package substrate 406, or between different locations on each face. In some embodiments, package substrate 406 may have a thickness less than 1 millimeter (e.g., between 0.1 millimeters and 0.5 millimeters), although any number of package geometries can be used. Additional conductive contacts 412 may be disposed at an opposite face of package substrate 406 for conductively contacting, for instance, a printed circuit board (PCB). One or more vias 410 extend through a thickness of package substrate 406 to provide conductive pathways between one or more of connections 408 to one or more of contacts 412. Vias 410 are illustrated as single straight columns through package substrate 406 for ease of illustration, although other configurations can be used (e.g., damascene, dual damascene, through-silicon via, or an interconnect structure that meanders through the thickness of substrate 406 to contact one or more intermediate locations therein). In still other embodiments, vias 410 are fabricated by multiple smaller stacked vias, or are staggered at different locations across package substrate 406. In the illustrated embodiment, contacts 412 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 412, to inhibit shorting.

In some embodiments, a mold material 414 may be disposed around the one or more dies 402 included within housing 404 (e.g., between dies 402 and package substrate 406 as an underfill material, as well as between dies 402 and housing 404 as an overfill material). Although the dimensions and qualities of the mold material 414 can vary from one embodiment to the next, in some embodiments, a thickness of mold material 414 is less than 1 millimeter. Example materials that may be used for mold material 414 include epoxy mold materials, as suitable. In some cases, the mold material 414 is thermally conductive, in addition to being electrically insulating.

Methodology

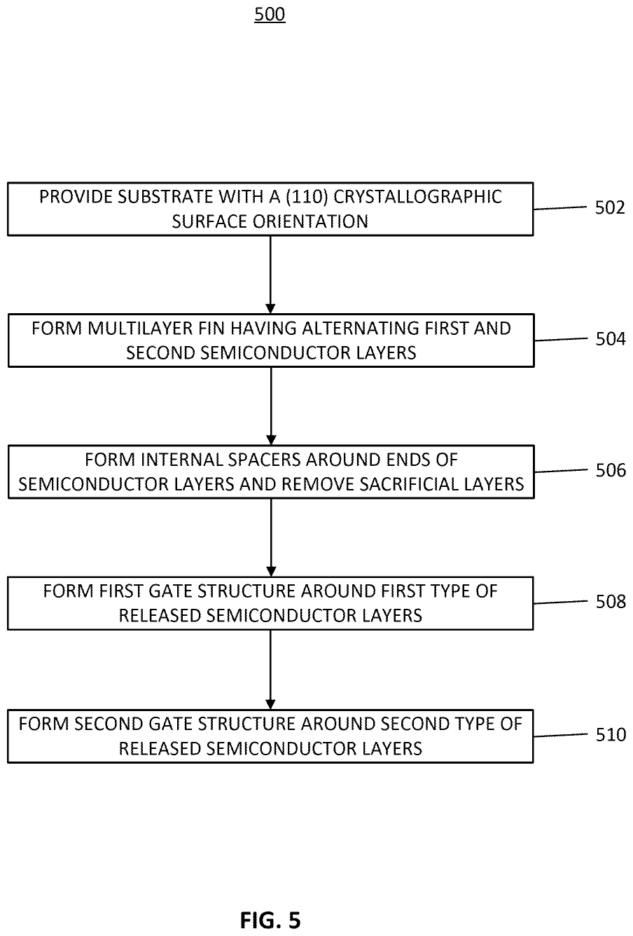

FIG. 5 is a flow chart of a method 500 for forming at least a portion of an integrated circuit, according to an embodiment. Various operations of method 500 may be illustrated in FIGS. 2A-2I. However, the correlation of the various operations of method 500 to the specific components illustrated in the aforementioned figures is not intended to imply any structural and/or use limitations. Rather, the aforementioned figures provide one example embodiment of method 500. Other operations may be performed before, during, or after any of the operations of method 500. Some of the operations of method 500 may be performed in a different order than the illustrated order.

Method 500 begins with operation 502 where a substrate is provided that has a (110) crystallographic surface orientation. The substrate may be a bulk silicon substrate or an SOI substrate with a top silicon layer having the (110) crystallographic surface orientation.

Method 500 continues with operation 504 where a multilayer fin is formed having alternating first semiconductor layers and second semiconductor layers. The first semiconductor layers may include Si while the second semiconductor layers may be SiGe or GeSn, to name a few examples. The germanium concentration of the SiGe semiconductor layers may be between 10% and 40% or between 20% and 30%, or at least 20%. The tin concentration of the GeSn semiconductor layers may be between 10% and 40% or between 20% and 30%, or at least 20%. The thickness of each of the first and second semiconductor layers may be between about 5 nm and about 20 nm or between about 5 nm and about 10 nm. Each of the first and second semiconductor layers may be deposited using any known material deposition technique, such as CVD, PECVD, PVD, or ALD. The fin of alternating material layers may be defined by patterning a sacrificial gate and spacer structures that extend orthogonally over the fin, then etching around the sacrificial gate and spacer structures via an anisotropic etching process, such as RIE.

Method 500 continues with operation 506 where internal spacers are formed around the ends of the first or second semiconductor layers while the other layers (e.g., sacrificial layers) and sacrificial gate are both removed. The internal spacers may have a material composition that is similar to or the exact same as spacer structures on either side of a sacrificial gate which runs orthogonally across the multilayer fin. Accordingly, the internal spacers may be any suitable dielectric material that exhibits high etch selectively to semiconductor materials such as silicon and/or silicon germanium.

According to some embodiments, the first semiconductor layers (e.g., the Si layers) of one or more p-channel devices are laterally etched back while the internal spacers fill the recesses between the first semiconductor layers. The internal spacers may be conformally deposited over the sides of the fin structure using a CVD process like ALD and then etched back using an isotropic etching process to expose the ends of the second semiconductor layers. Once the internal spacers have been formed, the sacrificial gate and sacrificial layers (e.g., the first semiconductor layers) may be removed from the fin, leaving behind suspended second semiconductor layers (e.g., SiGe or GeSn layers) that extend between a source and drain region (also formed following the formation of the internal spacers). One or more isotropic etching procedures may be performed to remove the sacrificial gate and sacrificial layers.

According to some embodiments, the second semiconductor layers (e.g., the SiGe or GeSn layers) of one or more n-channel devices are laterally etched back while the internal spacers fill the recesses between the second semiconductor layers. The internal spacers may be conformally deposited over the sides of the fin structure using a CVD process like ALD and then etched back using an isotropic etching process to expose the ends of the first semiconductor layers. Once the internal spacers have been formed, the sacrificial gate and sacrificial layers (e.g., the second semiconductor layers) may be removed from the fin, leaving behind suspended first semiconductor layers (e.g., Si layers) that extend between a source and drain region (also formed following the formation of the internal spacers). One or more isotropic etching procedures may be performed to remove the sacrificial gate and sacrificial layers.

Method 500 continues with operation 508 where a first gate structure is formed around the p-channel devices having suspended second semiconductor layers (e.g., the SiGe or GeSn layers). As discussed above, the first gate structure includes both a gate dielectric and a gate electrode formed over the gate dielectric. The first gate electrode may include one or more p-type work-function metals.

Method 500 continues with operation 510 where a second gate structure is formed around the n-channel devices having suspended first semiconductor layers (e.g., the Si layers). As discussed above, the second gate structure includes both a gate dielectric and a gate electrode formed over the gate dielectric. The second gate electrode may include one or more n-type work-function metals.

Example System

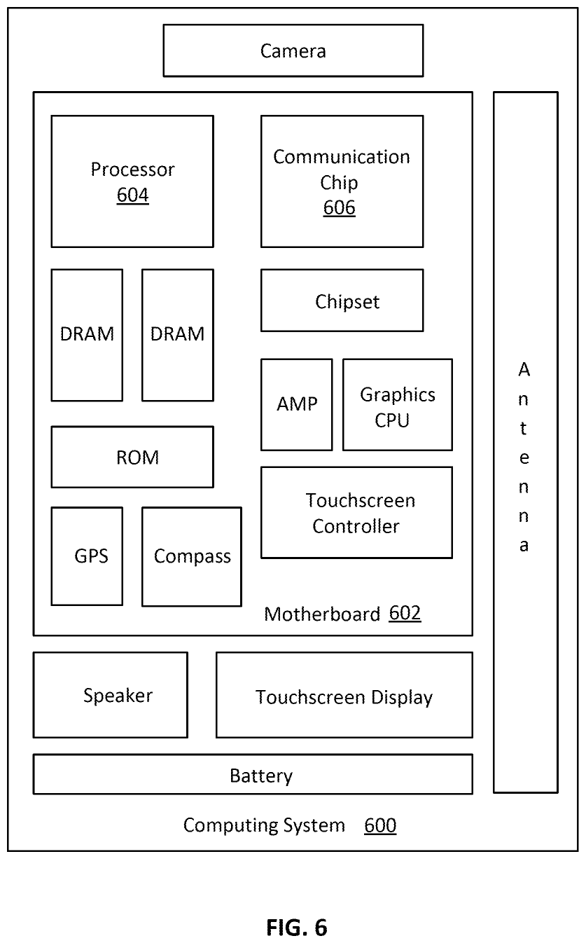

FIG. 6 is an example computing system implemented with one or more of the integrated circuit structures as disclosed herein, in accordance with some embodiments of the present disclosure. As can be seen, the computing system 600 houses a motherboard 602. The motherboard 602 may include a number of components, including, but not limited to, a processor 604 and at least one communication chip 606, each of which can be physically and electrically coupled to the motherboard 602, or otherwise integrated therein. As will be appreciated, the motherboard 602 may be, for example, any printed circuit board (PCB), whether a main board, a daughterboard mounted on a main board, or the only board of system 600, etc.

Depending on its applications, computing system 600 may include one or more other components that may or may not be physically and electrically coupled to the motherboard 602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 600 may include one or more integrated circuit structures or devices configured in accordance with an example embodiment (e.g., a module including an integrated circuit on a substrate, the substrate having a (110) crystallographic surface orientation). In some embodiments, multiple functions can be integrated into one or more chips (e.g., for instance, note that the communication chip 606 can be part of or otherwise integrated into the processor 604).

The communication chip 606 enables wireless communications for the transfer of data to and from the computing system 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing system 600 includes an integrated circuit die packaged within the processor 604. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 606 also may include an integrated circuit die packaged within the communication chip 606. In accordance with some such example embodiments, the integrated circuit die of the communication chip includes one or more semiconductor devices as variously described herein. As will be appreciated in light of this disclosure, note that multi-standard wireless capability may be integrated directly into the processor 604 (e.g., where functionality of any chips 606 is integrated into processor 604, rather than having separate communication chips). Further note that processor 604 may be a chip set having such wireless capability. In short, any number of processor 604 and/or communication chips 606 can be used. Likewise, any one chip or chip set can have multiple functions integrated therein.

In various implementations, the computing system 600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 600 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a substrate having a (110) crystallographic surface orientation, a semiconductor device on the substrate and having one or more bodies of semiconductor material extending in a first direction from a source region to a drain region, a first spacer structure that extends in a second direction orthogonal to the first direction and around first ends of the one or more bodies of semiconductor material, a second spacer structure that extends in the second direction and around second ends of the one or more bodies of semiconductor material, and a gate structure wrapped around the one or more bodies of semiconductor material and between the first and second spacer structures. Each of the one or more bodies of semiconductor material includes silicon and germanium.

Example 2 includes the subject matter of Example 1, wherein each of the one or more bodies of semiconductor material includes silicon and germanium along an entire length of that body of semiconductor material in the first direction.

Example 3 includes the subject matter of Example 1 or 2, wherein the one or more bodies of semiconductor material have a (110) crystallographic surface orientation along surfaces that are parallel with a plane extending in the first direction and the second direction.

Example 4 includes the subject matter of any one of Examples 1-3, wherein the concentration of germanium in each of the one or more bodies of semiconductor material is substantially consistent along an entire length of that body of semiconductor material in the first direction.

Example 5 includes the subject matter of any one of Examples 1-4, wherein the concentration of germanium in a central portion of each the one or more bodies of semiconductor material between the first and second spacer structures is substantially the same as the concentration of germanium at the corresponding first and second ends of the one or more bodies of semiconductor material.

Example 6 includes the subject matter of any one of Examples 1-5, wherein the concentration of germanium in the one or more semiconductor nanoribbons is between about 20% and about 30%.

Example 7 includes the subject matter of any one of Examples 1-6, wherein the semiconductor device is a first semiconductor device having one or more first bodies of semiconductor material, the integrated circuit further comprising a second semiconductor device on the substrate and having one or more second bodies of semiconductor material extending in the first direction from another source region to another drain region, wherein the one or more second bodies of semiconductor material include silicon and less than 1% germanium.

Example 8 includes the subject matter of Example 7, wherein any one of the one or more first bodies of semiconductor material and any one of the one or more second bodies of semiconductor material are not aligned on a common plane extending in the first and second directions.

Example 9 includes the subject matter of any one of Examples 1-8, wherein the source region and the drain region do not have visible crystal facets along a cross-section through the source region and the drain region extending along the first direction and a third direction that is orthogonal to both the first direction and the second direction.

Example 10 includes the subject matter of any one of Examples 1-9, wherein the one or more bodies of semiconductor material are nanoribbons.

Example 11 is a printed circuit board comprising the integrated circuit of any one of Examples 1-10.

Example 12 is an electronic device that includes a chip package comprising one or more dies. At least one of the one or more dies includes a substrate having a (110) crystallographic surface orientation, a semiconductor device on the substrate and having one or more semiconductor nanoribbons extending in a first direction from a source region to a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure wrapped around the one or more semiconductor nanoribbons and between the first and second spacer structures. Each of the one or more semiconductor nanoribbons includes silicon and germanium.

Example 13 includes the subject matter of Example 12, wherein the one or more semiconductor nanoribbons include silicon and germanium along an entire length of the one or more semiconductor nanoribbons in the first direction.

Example 14 includes the subject matter of Example 12 or 13, wherein the one or more semiconductor nanoribbons have a (110) crystallographic surface orientation along surfaces that are parallel with a plane extending in the first direction and the second direction.

Example 15 includes the subject matter of any one of Examples 12-14, wherein the concentration of germanium in each of the one or more semiconductor nanoribbons is substantially consistent along an entire length of the corresponding one or more semiconductor nanoribbons in the first direction.

Example 16 includes the subject matter of any one of Examples 12-15, wherein the concentration of germanium in a central portion of each of the one or more semiconductor nanoribbons between the first and second spacer structures is substantially the same as the concentration of germanium at the first and second ends of the corresponding one or more semiconductor nanoribbons.

Example 17 includes the subject matter of any one of Examples 12-16, wherein the concentration of germanium in the one or more semiconductor nanoribbons is between about 20% and about 30%.

Example 18 includes the subject matter of any one of Examples 12-17, wherein the semiconductor device is a first semiconductor device having one or more first semiconductor nanoribbons, the at least one of the one or more dies further comprising a second semiconductor device on the substrate and having one or more second semiconductor nanoribbons extending in the first direction between another source region and another drain region, wherein the one or more second semiconductor nanoribbons include silicon and less than 1% germanium.

Example 19 includes the subject matter of Example 18, wherein any one of the one or more first semiconductor nanoribbons and any one of the one or more second semiconductor nanoribbons are not aligned on a common plane extending in the first and second directions.

Example 20 includes the subject matter of any one of Examples 12-19, wherein the source region and the drain region do not have visible crystal facets along a cross-section through the source region and the drain region extending along the first direction and a third direction that is orthogonal to both the first direction and the second direction.

Example 21 includes the subject matter of any one of Examples 12-20, further comprising a printed circuit board, wherein the chip package is attached to the printed circuit board.

Example 22 is a method of forming an integrated circuit. The method includes providing a substrate having a (110) crystallographic surface orientation; epitaxially growing first material layers alternating with second material layers on the substrate, the second material layers comprising silicon (Si) and germanium (Ge); forming a multilayer fin from the first material layers and the second material layers; forming sidewall spacer structures around exposed ends of the second material layers; removing the first material layers to form suspended second material layers; forming source and drain regions coupled to the exposed ends of the second material layers; and forming a gate structure around the suspended second material layers and between the sidewall spacer structures.

Example 23 includes the subject matter of Example 22, wherein the first material layers comprise Si and less than 1% Ge.

Example 24 includes the subject matter of Example 22 or 23, wherein the second material layers include Si and Ge along an entire length of the second material layers between the source and drain regions.

Example 25 includes the subject matter of any one of Examples 22-24, wherein the concentration of Si and the concentration of Ge in the second material layers stays substantially consistent along an entire length of the second material layers between the source and drain regions.

Example 26 includes the subject matter of any one of Examples 22-25, wherein the second material layers have the same (110) crystallographic surface orientation as the substrate.

Example 27 is an integrated circuit that includes a semiconductor device having one or more semiconductor nanoribbons extending in a first direction between a source region and a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure around the one or more semiconductor nanoribbons and between the first and second spacer structures. Each of the one or more semiconductor nanoribbons includes silicon and germanium. The one or more semiconductor nanoribbons have a (110) crystallographic surface orientation along surfaces that are parallel with a plane extending in the first direction and the second direction.

Example 28 includes the subject matter of Example 27, wherein the one or more semiconductor nanoribbons include silicon and germanium along an entire length of the one or more semiconductor nanoribbons in the first direction.

Example 29 includes the subject matter of Example 27 or 28, further comprising a substrate having a (110) crystallographic surface orientation.

Example 30 includes the subject matter of any one of Examples 27-29, wherein the concentration of germanium in each of the one or more semiconductor nanoribbons is substantially consistent along an entire length of the corresponding one or more semiconductor nanoribbons in the first direction.

Example 31 includes the subject matter of any one of Examples 27-30, wherein the concentration of germanium in a central portion of each of the one or more semiconductor nanoribbons between the first and second spacer structures is substantially the same as the concentration of germanium at the first and second ends of the corresponding one or more semiconductor nanoribbons.

Example 32 includes the subject matter of any one of Examples 27-31, wherein the concentration of germanium in the one or more semiconductor nanoribbons is between about 20% and about 30%.

Example 33 includes the subject matter of any one of Examples 27-32, wherein the semiconductor device is a first semiconductor device having one or more first semiconductor nanoribbons, the integrated circuit further comprising a second semiconductor device having one or more second semiconductor nanoribbons extending in the first direction between another source region and another drain region, wherein the one or more second semiconductor nanoribbons include silicon and less than 1% germanium.

Example 34 includes the subject matter of Example 33, wherein any one of the one or more first semiconductor nanoribbons and any one of the one or more second semiconductor nanoribbons are not aligned on a common plane extending in the first and second directions.

Example 35 includes the subject matter of any one of Examples 27-34, wherein the source region and the drain region do not have visible crystal facets along a cross-section through the source region and the drain region extending along the first direction and a third direction that is orthogonal to both the first direction and the second direction.

Example 36 is a printed circuit board comprising the integrated circuit of any one of Examples 27-35.

Example 37 is an integrate circuit that includes a substrate having a (110) crystallographic surface orientation, a semiconductor device on the substrate and having one or more semiconductor nanoribbons extending in a first direction from a source region to a drain region, a first spacer structure that extends in a second direction orthogonal to the first direction and around first ends of the one or more semiconductor nanoribbons, a second spacer structure that extends in the second direction and around second ends of the one or more semiconductor nanoribbons, and a gate structure wrapped around the one or more semiconductor nanoribbons and between the first and second spacer structures. Each of the one or more semiconductor nanoribbons includes germanium and tin.

Example 38 includes the subject matter of Example 37, wherein the one or more semiconductor nanoribbons include germanium and tin along an entire length of the one or more semiconductor nanoribbons in the first direction.

Example 39 includes the subject matter of Example 37 or 38, wherein the one or more semiconductor nanoribbons have a (110) crystallographic surface orientation along surfaces that are parallel with a plane extending in the first direction and the second direction.

Example 40 includes the subject matter of any one of Examples 37-39, wherein the concentration of tin in each of the one or more semiconductor nanoribbons is substantially consistent along an entire length of the corresponding one or more semiconductor nanoribbons in the first direction.

Example 41 includes the subject matter of any one of Examples 37-40, wherein the concentration of tin in a central portion of each of the one or more semiconductor nanoribbons between the first and second spacer structures is substantially the same as the concentration of tin at the first and second ends of the corresponding one or more semiconductor nanoribbons.

Example 42 includes the subject matter of any one of Examples 37-41, wherein the concentration of tin in the one or more semiconductor nanoribbons is between about 20% and about 30%.

Example 43 includes the subject matter of any one of Examples 37-42, wherein the semiconductor device is a first semiconductor device having one or more first semiconductor nanoribbons, the at least one of the one or more dies further comprising a second semiconductor device on the substrate and having one or more second semiconductor nanoribbons extending in the first direction between another source region and another drain region, wherein the one or more second semiconductor nanoribbons include silicon and less than 1% tin.

Example 44 includes the subject matter of Example 43, wherein any one of the one or more first semiconductor nanoribbons and any one of the one or more second semiconductor nanoribbons are not aligned on a common plane extending in the first and second directions.

Example 45 includes the subject matter of any one of Examples 37-44, wherein the source region and the drain region do not have visible crystal facets along a cross-section through the source region and the drain region extending along the first direction and a third direction that is orthogonal to both the first direction and the second direction.

Example 46 is a printed circuit board comprising the integrated circuit of any one of Examples 37-45.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a substrate having a (110) crystallographic surface orientation;
a semiconductor device on the substrate, the semiconductor device having one or more bodies of semiconductor material extending in a first direction from a source region to a drain region;
a first spacer structure that extends in a second direction orthogonal to the first direction and around first ends of the one or more bodies of semiconductor material;
a second spacer structure that extends in the second direction and around second ends of the one or more bodies of semiconductor material; and
a gate structure wrapped around the one or more bodies of semiconductor material and between the first and second spacer structures;
wherein each of the one or more bodies of semiconductor material includes silicon and germanium.

2. The integrated circuit of claim 1, wherein the one or more bodies of semiconductor material have a (110) crystallographic surface orientation along surfaces that are parallel with a plane extending in the first direction and the second direction.

3. The integrated circuit of claim 1, wherein the concentration of germanium in each of the one or more bodies of semiconductor material is substantially consistent along an entire length of that body of semiconductor material in the first direction.

4. The integrated circuit of claim 1, wherein the semiconductor device is a first semiconductor device having one or more first bodies of semiconductor material, the integrated circuit further comprising a second semiconductor device on the substrate and having one or more second bodies of semiconductor material extending in the first direction from another source region to another drain region, wherein the one or more second bodies of semiconductor material include silicon and less than 1% germanium.

5. The integrated circuit of claim 4, wherein any one of the one or more first bodies of semiconductor material and any one of the one or more second bodies of semiconductor material are not aligned on a common plane extending in the first and second directions.

6. The integrated circuit of claim 1, wherein the source region and the drain region do not have visible crystal facets along a cross-section through the source region and the drain region extending along the first direction and a third direction that is orthogonal to both the first direction and the second direction.

7. A printed circuit board comprising the integrated circuit of claim 1.

8. An electronic device, comprising:
a chip package comprising one or more dies, at least one of the one or more dies comprising
a substrate having a (110) crystallographic surface orientation;
a semiconductor device on the substrate, the semiconductor device having one or more semiconductor nanoribbons extending in a first direction between a source region and a drain region;
a first spacer structure that extends in a second direction orthogonal to the first direction and around first ends of the one or more semiconductor nanoribbons;
a second spacer structure that extends in the second direction and around second ends of the one or more semiconductor nanoribbons; and
a gate structure around the one or more semiconductor nanoribbons and between the first and second spacer structures;
wherein each of the one or more semiconductor nanoribbons includes silicon and germanium.

9. The electronic device of claim 8, wherein the one or more semiconductor nanoribbons include silicon and germanium along an entire length of the one or more semiconductor nanoribbons in the first direction.

10. The electronic device of claim 8, wherein the one or more semiconductor nanoribbons have a (110) crystallographic surface orientation along surfaces that are parallel with a plane extending in the first direction and the second direction.

11. The electronic device of claim 8, wherein the semiconductor device is a first semiconductor device having one or more first semiconductor nanoribbons, the at least one of the one or more dies further comprising a second semiconductor device on the substrate and having one or more second semiconductor nanoribbons extending in the first direction between another source region and another drain region, wherein the one or more second semiconductor nanoribbons include silicon and less than 1% germanium.

12. The electronic device of claim 11, wherein any one of the one or more first semiconductor nanoribbons and any one of the one or more second semiconductor nanoribbons are not aligned on a common plane extending in the first and second directions.

13. The electronic device of claim 8, wherein the source region and the drain region do not have visible crystal facets along a cross-section through the source region and the drain region extending along the first direction and a third direction that is orthogonal to both the first direction and the second direction.

14. The electronic device of claim 8, further comprising a printed circuit board, wherein the chip package is attached to the printed circuit board.

15. An integrated circuit comprising:
a semiconductor device, the semiconductor device having one or more semiconductor nanoribbons extending in a first direction between a source region and a drain region;
a first spacer structure that extends in a second direction orthogonal to the first direction and around first ends of the one or more semiconductor nanoribbons;
a second spacer structure that extends in the second direction and around second ends of the one or more semiconductor nanoribbons; and
a gate structure around the one or more semiconductor nanoribbons and between the first and second spacer structures;
wherein each of the one or more semiconductor nanoribbons includes silicon and germanium, and wherein the one or more semiconductor nanoribbons have a (110) crystallographic surface orientation along surfaces that are parallel with a plane extending in the first direction and the second direction.

16. The integrated circuit of claim 15, wherein the one or more semiconductor nanoribbons include silicon and germanium along an entire length of the one or more semiconductor nanoribbons in the first direction.

17. The integrated circuit of claim 15, further comprising a substrate having a (110) crystallographic surface orientation.

18. The integrated circuit of claim 15, wherein the concentration of germanium in a central portion of each of the one or more semiconductor nanoribbons between the first and second spacer structures is substantially the same as the concentration of germanium at the first and second ends of the corresponding one or more semiconductor nanoribbons.

19. The integrated circuit of claim 15, wherein the semiconductor device is a first semiconductor device having one or more first semiconductor nanoribbons, the integrated circuit further comprising a second semiconductor device having one or more second semiconductor nanoribbons extending in the first direction between another source region and another drain region, wherein the one or more second semiconductor nanoribbons include silicon and less than 1% germanium.

20. The integrated circuit of claim 15, wherein the source region and the drain region do not have visible crystal facets along a cross-section through the source region and the drain region extending along the first direction and a third direction that is orthogonal to both the first direction and the second direction.
